(19) United States
(12) Patent Application Publication
(10) Pub. No.: US 2008/0056035 A1
(43) Pub. Date: Mar. 6, 2008

(54) Method and apparatus for adaptive programming of flash memory, flash memory devices, and systems including flash memory having adaptive programming capability

(75) Inventor: Hagop A. Nazarian, San Jose, CA (US)

Correspondence Address: DICKSTEIN SHAPIRO LLP, 1825 EYE STREET, NW, WASHINGTON, DC, 20006, US

(73) Assignee: Micron Technology, Inc.

(21) Appl. No.: 11/513,266

(22) Filed: Aug. 31, 2006

(51) Int. Cl. G11C 16/06; G11C 11/34; G11C 7/00; G11C 29/00

(52) U.S. Cl. 365/201; 365/185.28; 365/185.19; 365/185.22

(57) ABSTRACT

A flash memory device, a system including a flash memory device, a method for operating a flash memory cell, and an apparatus for operating a flash memory cell include applying a first bit line voltage to a bit line coupled to the cell, applying a first test voltage to a word line coupled to the cell, storing a first threshold voltage value for the cell, applying a second test voltage to the word line, storing a second threshold voltage value for the cell, and determining a programming pulse voltage for the cell from the first and second stored threshold voltage values.

### FIELD OF THE INVENTION

The invention relates to methods and apparatuses for the programming of flash memory cells.

### BACKGROUND OF THE INVENTION

Current technologies for programming flash memory cells, e.g., NAND flash memory cells, include a technique where a series of pulses of increasing voltage magnitude is used for programming. For example, as shown in FIG. 1, which is a simplified portion of a NAND flash memory array, a selected cell 11 in a NAND array 10 is typically programmed by applying a channel voltage to a selected bit line BL₀ and a word line voltage to a selected word line WL₁. The bit lines BL₀, BL₁ are connected to a cache 18. The bit lines BL₀, BL₁ are also terminated, along with the strings of cells, including cell 11, at a ground potential. In order to program a cell to a desired threshold voltage Vₜ for cell 11, a series of pulses of increasing voltage magnitude is used, as depicted in FIG. 2.

Programming begins with a first pulse P₁ of voltage magnitude M₁ applied to a gate 14 of the cell 11 via the word line WL₁ while approximately 0V is applied to the channel 15 of the cell 11 via the bit line BL₀; a higher voltage (e.g., a supply voltage V_{cc}) is applied to a gate 16 of a first enabling transistor 12; and approximately 0V is applied to a gate 17 of a second enabling transistor 13. Then, during a subsequent read verify period V₁, the cell 11 is checked to see if the cell was programmed to a desired Vₜ value. In actuality, all cells in a row which need to be programmed from an erased state are programmed simultaneously with voltages applied to the bit lines BL₀, BL₁ of the cells in the row to be programmed, along with a common programming word line voltage. Those cells in a row which are not to be programmed have a voltage higher than 0V, typically a supply voltage V_{cc}, applied to their bit lines, while approximately 0V is applied to the gate 16 of the first enabling transistor 12; and a higher voltage (e.g., a supply voltage V_{cc}) is applied to the gate 17 of the second enabling transistor 13.

Conventional programming of NAND flash cells with data primarily occurs in several iterative operations. These operations are selected and applied to all the cells based on the data content of the data, e.g., “0” or “1”. Conventional programming operations include:

(1) Programming: shifts/changes the threshold voltage Vₜ of the cell to alter the logic state of the cell. Programming the cell is accomplished by grounding the channel of the selected cell, and applying incremental voltage pulses as shown in FIG. 2 to the selected word line that is connected to the gate of the selected cell. The high potential voltage generated between the channel and the word line enable tunneling of the electrons into the floating gate and shift the Vₜ of the cell in a positive direction.

(2) Inhibit Programming: disables the programming of the cell if verification is passed. Inhibiting a cell from being programmed on the selected word line that has incremental voltage pulses is accomplished by letting the channel, source, and drain of the selected cell float and coactively couple with the high voltage pulses that are applied on the word line to program other cells. The reduced potential voltage between the channel, source, drain, and word line of the cell will inhibit electron tunneling and programming.

To float the channel and the bit lines of a selected device to be inhibited, the bit line associated with the cell that needs to be inhibited is raised to a positive voltage, e.g., Vcc, such that it is higher then the gate of the select gate transistor according to the equation:

V_{blinhibit}>>V_{gs}−Vₜ (1)

where V_{blinhibit} is the voltage applied to the bit line to inhibit programming, V_{gs} is the voltage applied to the gate of the selected cell, and Vₜ is the threshold voltage of the selected cell. When the word line voltage is increasing, the floating channel under the cell will couple and follow the word line high voltage pulses.

(3) Program Verify: senses/measures the threshold voltage Vₜ of the cell and returns a pass or fail status to the programming circuits to enable the system to continue programming if it failed or inhibit programming if it passed.

While the word line high voltage pulses are being programmed, inhibit programming operations may be simultaneously applied to the same row of cells connected to the selected word line. A program verify operation is applied before and after every high programming voltage pulse. If a cell passed the target program threshold voltage Vₜ, the cell will be inhibited during the subsequent programming pulses.

It is well known that not all cells in a row desired to be programmed will program with an identical word line programming pulse, some cells program faster than other cells, i.e., at lower programming voltages. Consequently, during a read/verify period V₁, where all cells in a row are read, if the verify circuit determines that not all cells which should be programmed to a desired Vₜ were so programmed, a next programming operation occurs. In the next programming operation, those cells which were successfully programmed are inhibited for further programming by applying the inhibiting conditions described above, with a voltage of approximately V_{cc} to the associated bit line, while the next word line programming pulse P₂, having a magnitude M₂ greater than magnitude M₁, is applied to the word line and the unprogrammed cells receive the programming bit line voltage, e.g., 0V, on their respective bit lines.

This process of applying programming voltages to the unprogrammed cells, with an increasing word line programming voltage, continues to occur until all cells on a word line, desired to be programmed, are verified as, in fact, programmed. In current practice, the initial word line programming pulse P₁ may have a programming voltage magnitude M₁ of approximately 16V, and subsequent word line programming pulses P₂ . . . Pₙ have an increasing magnitude to an upper programming voltage magnitude Mₙ of approximately 20V. During programming, the bit lines for cells to be programmed are set to approximately 0V. The bit line voltage applied when programmed cells in a row are inhibited for further programming in a subsequent programming cycle is, as noted, approximately V_{cc}, the working voltage of the flash memory device.

There are two detrimental effects associated with the programming procedure described above. First, it takes time to program all cells in an array when each word line may potentially go through several word line programming pulses of increasing magnitude. This causes a considerable time to program new data into a flash memory device and accounts for much of the slowness attributed to flash memory devices.

A second detrimental effect is known as “word line disturb,” in which, even though faster programming cells are inhibited from subsequent programming cycles, the increasing magnitude of word line pulses applied to the inhibited cells may still disturb the previously programmed threshold voltage Vₜ from a desired value. This is particularly a problem when multi-level programming of a cell is employed where any given cell may be programmed to one of a plurality of possible threshold values Vₜ. Any shift in a programmed threshold value Vₜ towards a different possible threshold value which may be programmed in the cell causes possible ambiguity in the readout value of the programmed cell. Shifting Vₜ too high is referred to as “overprogramming.”

A method and apparatus for mitigating these deleterious effects in flash memory programming is desirable.

### BRIEF DESCRIPTION OF THE DRAWINGS

FIG. 1 depicts in schematic form a portion of a flash memory array.

FIG. 2 depicts the conventional word line programming use in programming cells of the FIG. 1 array.

FIG. 3 depicts a graph, useful in explaining the invention, of threshold voltages Vₜ for a flash memory cell as a function of applied word line programming voltages for a fast programming cell and a slow programming cell.

FIG. 4 depicts a flowchart of a method in accordance with an embodiment of the invention.

FIG. 5 depicts the word line and bit line programming used in programming cells in accordance with an embodiment of the invention.

FIG. 6 depicts in block format a circuit for implementing an embodiment of the invention, within a flash memory device.

FIG. 7A depicts a first portion of a circuit for measuring threshold voltages of a memory cell in accordance with an embodiment of the invention.

FIG. 7B depicts a second portion of a circuit for measuring threshold voltages of a memory cell in accordance with an embodiment of the invention.

FIG. 7C depicts a graph, useful in explaining the circuits of FIGS. 7A and 7B, of bit line voltages for a flash memory cell as a function of applied word line programming voltages for a fast programming cell and a slow programming cell.

FIG. 8 depicts a first circuit for producing a bit line programming voltage according to an embodiment of the invention.

FIG. 9 depicts a second circuit for producing a bit line programming voltage according to an embodiment of the invention.

FIG. 10 depicts a third circuit for producing a bit line programming voltage according to an embodiment of the invention.

FIG. 11 depicts a flash memory device incorporating an apparatus constructed in accordance with an embodiment of the invention.

FIG. 12 depicts a processor system incorporating a flash memory device constructed in accordance with an embodiment of the invention.

### DETAILED DESCRIPTION OF THE INVENTION

In the following detailed description, reference is made to the accompanying drawings, which form a part hereof and show by way of illustration specific embodiments in which the invention may be practiced. These embodiments are described in sufficient detail to enable those skilled in the art to practice them, and it is to be understood that other embodiments may be utilized, and that structural, logical, and electrical changes may be made without departing from the spirit and scope of the present invention. The progression of processing steps described is exemplary of the embodiments of the invention; however, the sequence of steps is not limited to that set forth herein and may be changed as is known in the art, with the exception of steps necessarily occurring in a certain order.

Embodiments of the invention include methods and apparatuses for programming a NAND flash memory cell. As will be described in detail below, a first and second test pulse are applied to the word line of the cell, and the threshold voltage of the cell is measured after each test pulse. The measured threshold voltages are used to extrapolate the estimated programming pulse voltage or voltages, by applying the maximum word line voltage while applying an extrapolated bit line voltage, which is set so that the difference between the maximum word line voltage and the bit line voltage is equal to the estimated programming pulse voltage. Additional steps may include verifying the threshold voltage of the cell and applying additional bit line voltages until a desired threshold voltage of the cell is reached. Embodiments of the invention further include devices and systems for programming a NAND flash memory cell as described herein.

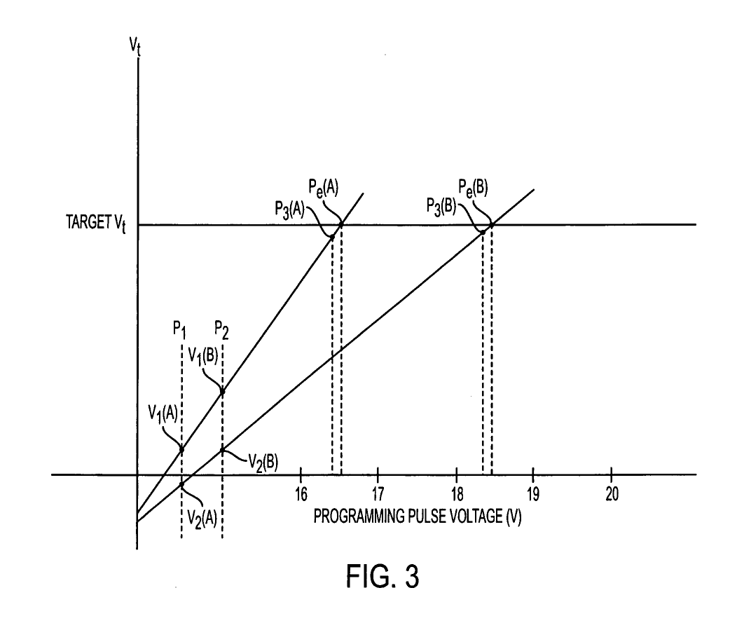

FIG. 3 depicts a graph, useful in explaining an embodiment of the invention, of threshold voltages Vₜ for a flash memory cell as a function of applied word line programming voltage for a fast programming cell and a slow programming cell. Line A represents a fast programming cell A. Line B represents a slow programming cell B.

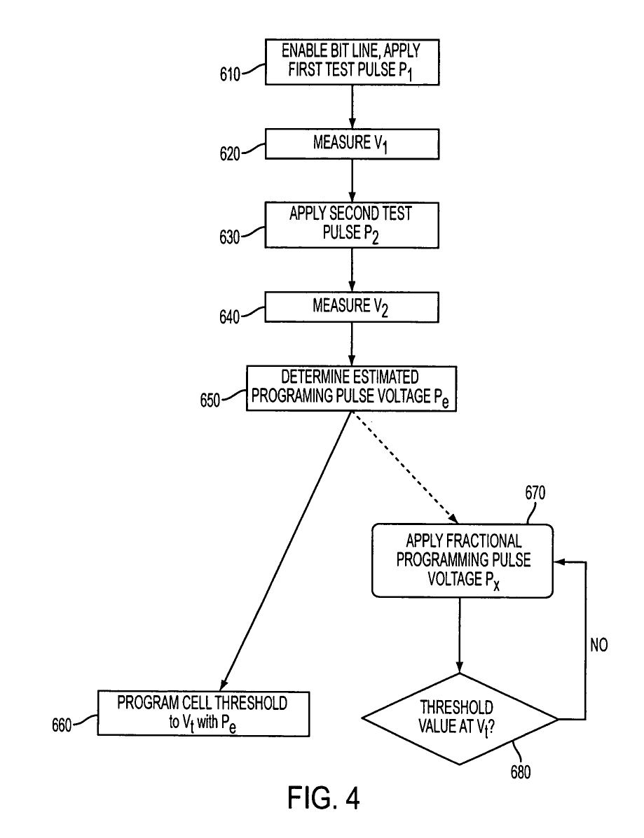

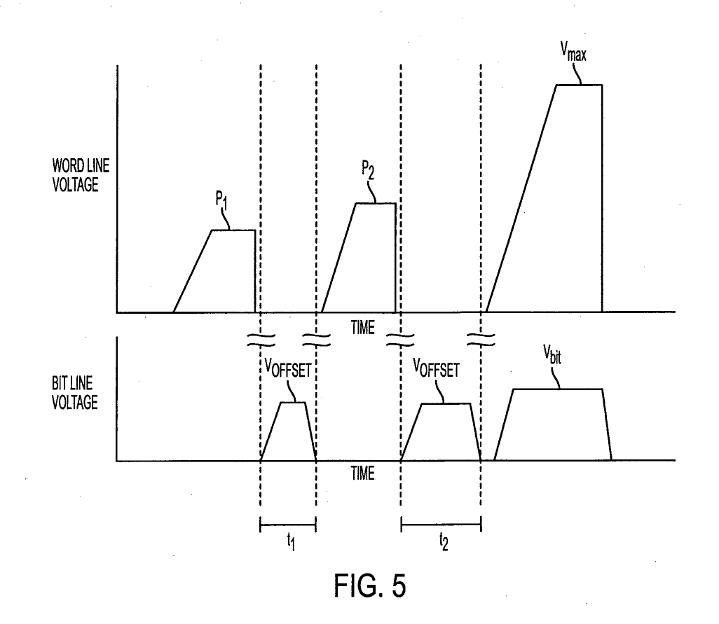

FIG. 4 depicts a flowchart of a programming method in accordance with an embodiment of the invention, for each cell of a row of an array, including cells A and B. At step 610, the bit line BL₀ for each cell to be programmed is set to approximately 0V, while a first test pulse P₁ is applied to the word line. FIG. 5 depicts the word line and bit line programming pulses used in programming cells in accordance with an embodiment of the invention. At step 620, a first threshold value V₁ is sampled for each cell as V₁(A) and V₁(B) during time period t₁ (FIG. 5), while the bit line voltage is raised to an offset value V_{offset}. The offset value V_{offset} is selected to match a threshold voltage of the enable transistors 12, 17, typically 0.7V. Then, at step 630, a second test pulse P₂ is applied to the word line of each cell. Next, at step 640, a second threshold value V₂ is sampled for each cell as V₂(A) and V₂(B) during time period t₂ (FIG. 5), while the bit line voltage is again raised to the offset value V_{offset}. It should be appreciated that, while FIG. 3 illustrates just two cells of the array in a row line, that in practice, all cells in a row receive the test pulses P₁ and P₂, and have values of V₁ and V₂ determined for them.

An estimated programming pulse voltage Pₑ for each cell can be extrapolated (step 650) from the measured values V₁(A), V₂(A), and V₁(B), V₂(B). In this example, a line with slope V₂(A)−V₁(A) intersects the target threshold voltage level Vₜ at an estimated programming pulse voltage Pₑ(A) of approximately 16.5V for fast-programming cell A. A line with slope V₂(B)−V₁(B) intersects the target threshold voltage level Vₜ at an estimated programming pulse voltage Pₑ(B) of approximately 18.5V for slow-programming cell B. The extrapolation may be calculated within the flash memory device, or may be selected from a predetermined list of look-up values, or other appropriate procedure.

As an example calculation, Pₑ may be calculated by:

Pₑ=k(V₂−V₁) (2)

where V₁ and V₂ are the first and second measured threshold values, and k is a correlation factor which is determined experimentally based on the cell characteristics, e.g. coupling ratio. The correlation factor k may be calculated to satisfy the following equation:

k=(V₂−V₁)/(P₂−P₁) (3)

where P₁ and P₂ are the first and second test pulses. Equation (3) presumes that the bit line programming voltage V_{bit} and the voltage on the channel of the cell V_{ch} satisfy:

V_{bit}=V_{ch}=0V (4)

Using the estimated programming pulse voltages Pₑ(A), Pₑ(B), the cells A, B are then programmed (step 660) to the target threshold voltage Vₜ. In order to achieve the desired programming pulse voltage Pₓ, a maximum word line voltage Vₘₐₓ (e.g., 20V) is applied to the word line, while a bit line programming voltage V_{bit} is applied to the bit line. The bit line programming voltage V_{bit} is selected to satisfy the equations:

(Pₑ−V₂)=k(Vₘₐₓ−P₂−V_{bit}) (5)

V_{bit}=Vₘₐₓ−P₂−(Pₑ−V₂)/k (6)

In addition, the voltage on the channel of the cell V_{ch} satisfies the equation:

V_{ch}=V_{bit} (7)

Accordingly, for programming, each cell in a row receives a same high word line voltage Vₘₐₓ, but the bit line voltages V_{bit} differ, based on the speed of programming of the individual cells as determined from the acquired measured threshold voltages V₁ and V₂ for each cell. In this manner, the cells A, B may be programmed using as few as three pulses P₁, P₂, and Pₑ. All cells in the array would be subjected to fewer pulses during each programming cycle, thereby avoiding 1) a high number of pulses which may cause the cells to degrade over time, 2) overprogramming due to word line disturb, and 3) slow programming times.

In an another embodiment, in order to avoid overprogramming, at optional step 670, a fractional pulse P₃(A), P₃(B) of lower magnitude than the full estimated programming pulse voltage Pₑ(A), Pₑ(B) may be used. In this embodiment, values of 90% of the estimated programming pulse voltages P₃(A), P₃(B) may be used. The threshold values for each cell A, B may then be verified at step 680, and additional programming pulses P₄, P₅, . . . , Pₙ, at higher voltages may be used if needed by repeating steps 670 and 680 until the desired threshold voltage is reached. Such additional programming pulses may be at the estimated programming pulse voltage, or at some fraction thereof (e.g., 99% of P₃(A) or P₃(B)).

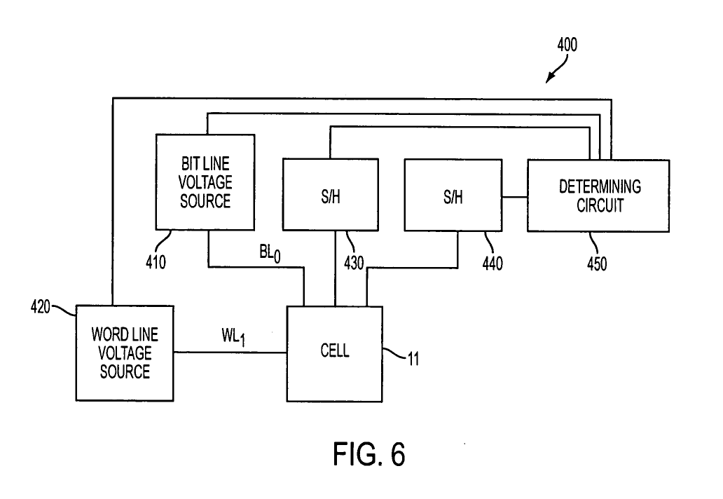

FIG. 6 depicts in block format a circuit 400 for implementing an embodiment of the invention, within a flash memory device. Circuit 400 includes a bit line voltage source 410, a word line voltage source 420, first sample-and-hold circuit 430, and a determining circuit 450. Circuit 400 may also include an optional second sample-and-hold circuit 440. Bit line voltage source 410 is coupled to cell 11 via its associated bit line BL₀. Word line voltage source 420 is coupled to cell 11 via its associated word line WL₁. The two voltage sources 410, 420 are used as described with reference to FIG. 3 to program cell 11. First and second sample-and-hold circuits 430, 440 sample and store measured values V₁(11), V₂(11). Determining circuit 450 receives the measured values V₁(11), V₂(11) and determines the estimated programming pulse voltage Pₑ(11). If the optional second sample-and-hold circuit 440 is not used, the first sample-and-hold circuit 430 will sample and store measured value V₁(11), and measured value V₂(11), will be sampled and received directly by determining circuit 450. Furthermore, determining circuit 450 controls the two voltage sources 410, 420 to program cell 11 with the estimated programming pulse voltage Pₑ(11), or with one or more fractional pulses Pₙ using a high word line voltage Vₘₐₓ and applied bit line voltages V_{bit} as described above.

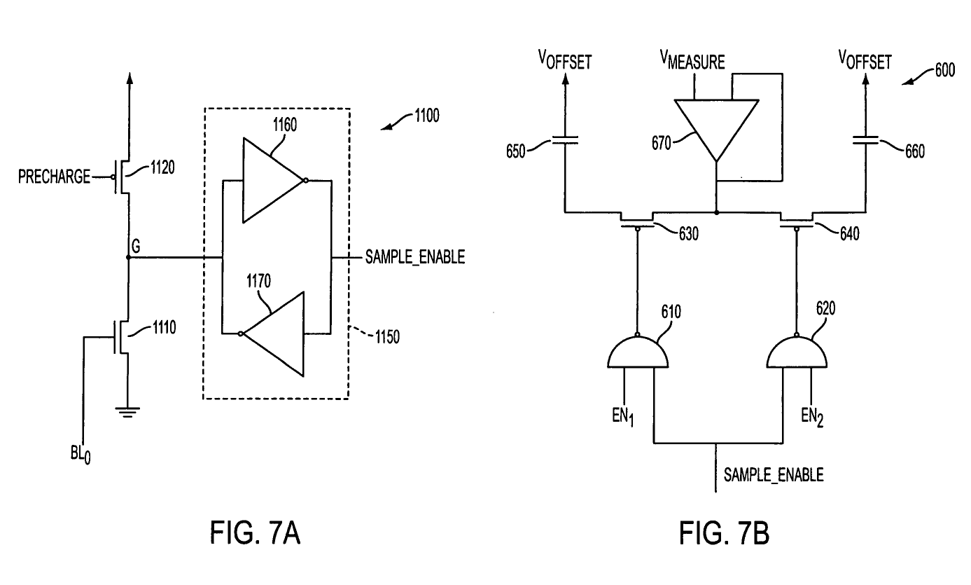

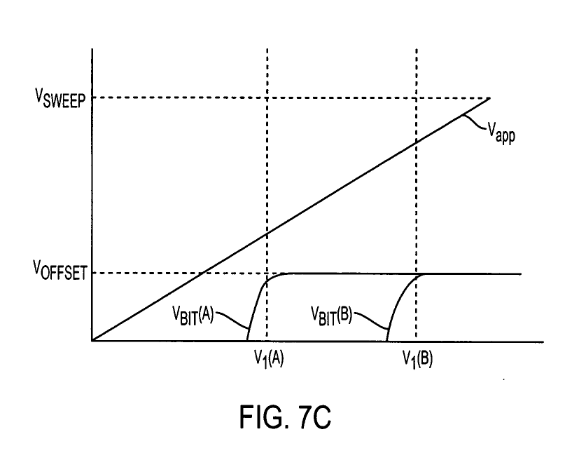

FIG. 7A depicts a circuit 1100, which is a first portion of a circuit for measuring threshold voltages V₁, V₂ of a memory cell in accordance with an embodiment of the invention. Circuit 1100 includes an n-type transistor 1110, which has a gate coupled to the bit line BL0, a first source/drain region coupled to a ground potential, and a second source/drain region coupled to a node G. A p-type transistor 1120 has a first source/drain region coupled to the node G and a second source/drain region coupled to a supply voltage, and is activated by an enable signal Precharge. The node G is further connected to a latch 1150, which includes looped first and second inverters 1160, 1170. Latch 1150 has an output sample_enable which outputs a logical 0 or 1 value.

FIG. 7B depicts a circuit 600, which is a second portion of a circuit for measuring threshold voltages V₁, V₂ of a memory cell 11 in accordance with an embodiment of the invention. Circuit 600 includes first and second NAND gates 610, 620, each with a first input connected to the output sample_enable of latch 1150 (FIG. 7A). The other input of the first NAND gate 610 is connected to a first enable signal EN1. The other input of the second NAND gate 620 is connected to a second enable signal EN2. The first and second NAND gates 610, 620 have respective outputs connected to the gates of first and second p-type transistors 630, 640. The first transistor 630 has a source/drain region coupled to one terminal of a first storage capacitor 650 and a second source/drain region coupled to an output of a operational amplifier 670. The second transistor 640 has a source/drain region coupled to one terminal of a second storage capacitor 660 and a second source/drain region coupled to the output of the operational amplifier 670. An offset voltage V_{offset} is applied to the other terminals of first and second storage capacitors 650, 660.

The operational amplifier 670 has an input connected to a voltage source Vₘₑₐₛᵤᵣₑ, which is set to the same applied voltage Vₐₚₚ as the word line WL₁. During operation, both Vₘₑₐₛᵤᵣₑ and the applied voltage Vₐₚₚ are gradually increased as described below with reference to FIG. 7C. The first enable signal EN1 is asserted, and the first storage capacitor 650 samples and stores V₁ (via Vₘₑₐₛᵤᵣₑ). Then the second enable signal EN2 is asserted, and the second storage capacitor 660 samples and stores V₂ (via Vₘₑₐₛᵤᵣₑ).

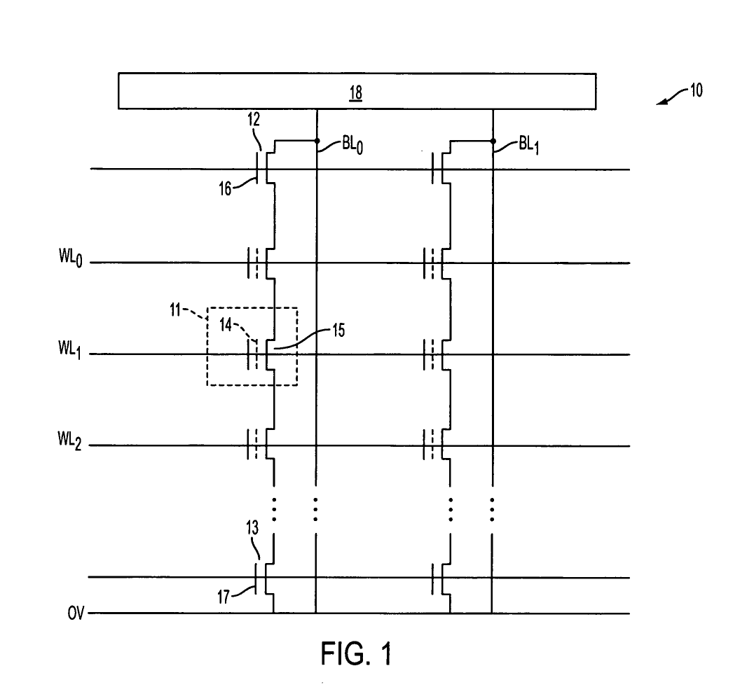

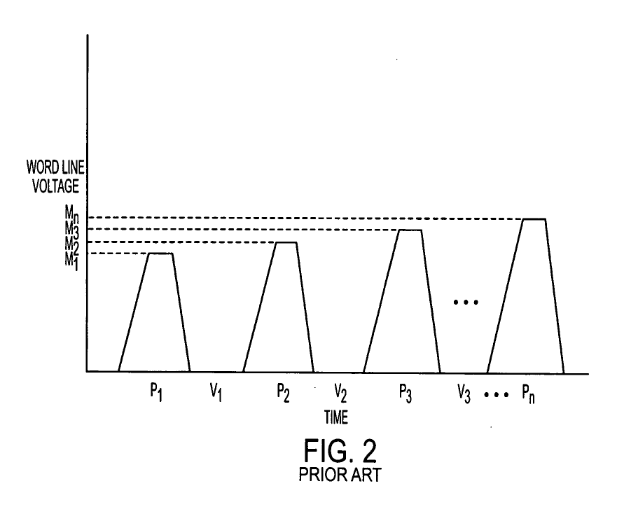

FIG. 7C depicts a graph, useful in explaining the circuits of FIGS. 7A and 7B, of bit line voltages V_{bit}(A), V_{bit}(B) for a flash memory cell as a function of applied word line programming voltages Vₐₚₚ for a fast programming cell A and a slow programming cell B. First, the bit line BL₀ is discharged, causing the bit line voltages V_{bit}(A), V_{bit}(B) to be approximately 0V. Then, an offset voltage V_{offset} is applied to the second enable transistor 13 of circuit 10 (FIG. 1). The enable signal Precharge (FIG. 7A) turns on transistor 1120 while a voltage Vₐₚₚ is applied to the word line WL₁. The first enable signal EN1 is applied to the first NAND gate 610. The applied word line voltage Vₐₚₚ is gradually increased from approximately 0V to a maximum sweep voltage V_{sweep}. The applied word line voltage Vₐₚₚ may be stepped up in increments or continuously increased.

When the applied word line voltage Vₐₚₚ reaches a voltage equal to the difference between the cell threshold voltage and the offset voltage, the bit line voltage V_{bit} will increase when the threshold voltage of the cell 11 is reached. The threshold voltage being reached causes the offset voltage to be passed to the gate of transistor 1110, which is then activated, and causes the latch 1150 to be set, at which time the applied word line voltage Vₐₚₚ is measured by charge on the first storage capacitor 650 of FIG. 7 to obtain the first test threshold voltage V₁ of the cell 11, which is calculated as:

V₁=Vₐₚₚ−V_{offset} (8)

A fast programming cell A sets the latch 1150 at a threshold voltage V₁(A), and a slow programming cell B sets the latch 1150 at a threshold voltage V₁(B). The procedure is repeated with the second enable signal EN2 applied to the second NAND gate 620 to obtain the second test threshold voltage V₂ of the cell 11 and hold the charge on capacitor 660.

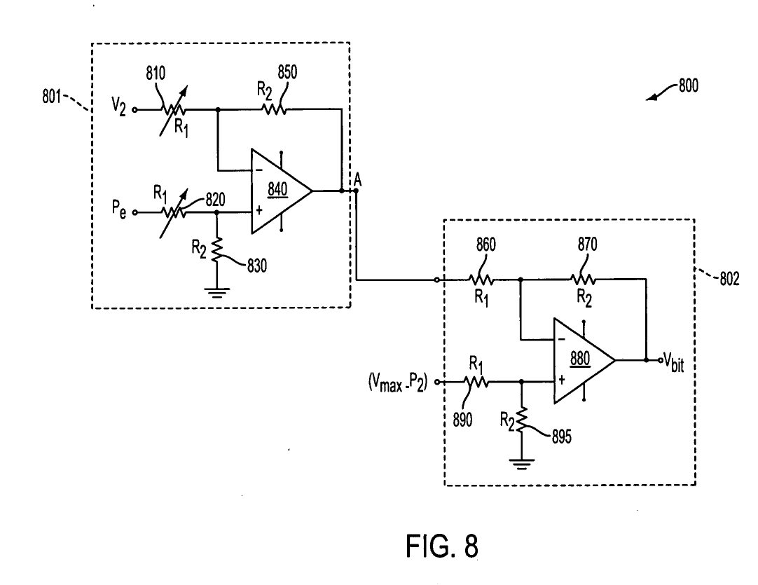

FIG. 8 depicts a first circuit 800 for producing a bit line programming voltage according to an embodiment of the invention. Circuit 800 includes first and second difference circuits 801, 802. First difference circuit 801 includes a first resistor 810 of variable resistance R₁ and a second resistor 850 of resistance R₂ connected to an inverting input of a first operational amplifier 840. The second resistor 850 is connected at its other terminal to the output of the first operational amplifier 840. A third resistor 820 of variable resistance R₁ and a fourth resistor 830 of resistance R₂ are connected to a non-inverting input of the first operational amplifier 840. The fourth resistor 830 is connected at its other terminal to a ground potential.

Second difference circuit 802 includes a fifth resistor 860 of resistance R₁ having a first terminal connected to the output of the first operational amplifier 840, and a second terminal connected to an inverting input of a second operational amplifier 880 and to one terminal of a sixth resistor 870 of resistance R₂. The sixth resistor 870 is connected at its other terminal to the output of the second operational amplifier 880. A seventh resistor 890 of resistance R₁ and a eighth resistor 895 of resistance R₂ are connected to a non-inverting input of the second operational amplifier 880. The eighth resistor 895 is connected at its other terminal to a ground potential.

The input of the first variable resistor 810 is the second threshold voltage value V₂, which may, for example, be previously sampled and stored by the second capacitor 660 (FIG. 7B). The input of the third variable resistor 820 is the estimated programming pulse voltage Pₑ, which is previously determined, for instance, by a determining circuit (e.g., determining circuit 450 (FIG. 4)) according to equation (2). The input of the seventh resistor 890 is determined by a difference circuit (not shown), which produces (Vₘₐₓ−₂). The output of the second operational amplifier 880 is the bit line programming voltage V_{bit}. The voltage V_{A} at node A satisfies the equation:

V_{A}=(Pₑ−V₂)(R₂/R₁) (9)

The bit line programming voltage V_{bit} satisfies the equation:

V_{bit}=((Vₘₐₓ−P₂)−V_{A})(R₂/R₁) (10)

If equation (9) is substituted for V_{A} in equation (10), the result is equation (6). Resistances R₁ and R₂ may be selected to produce the desired threshold value Vₜ based on the desired accuracy, e.g., 80-90%.

In an another embodiment, after the cell has been programmed once, soft programming may be performed during an erase operation, in which the cell 11 is set to a known erase threshold value, which is verified as with the first test pulse P₁ and verification as described above. Therefore, during the next programming operation, only one additional measured threshold value V₂ and test pulse P₂ is required, or, alternatively, the correlation factor k may be adjusted to reach a smaller threshold value, e.g., 80% of the target threshold value Vₜ.

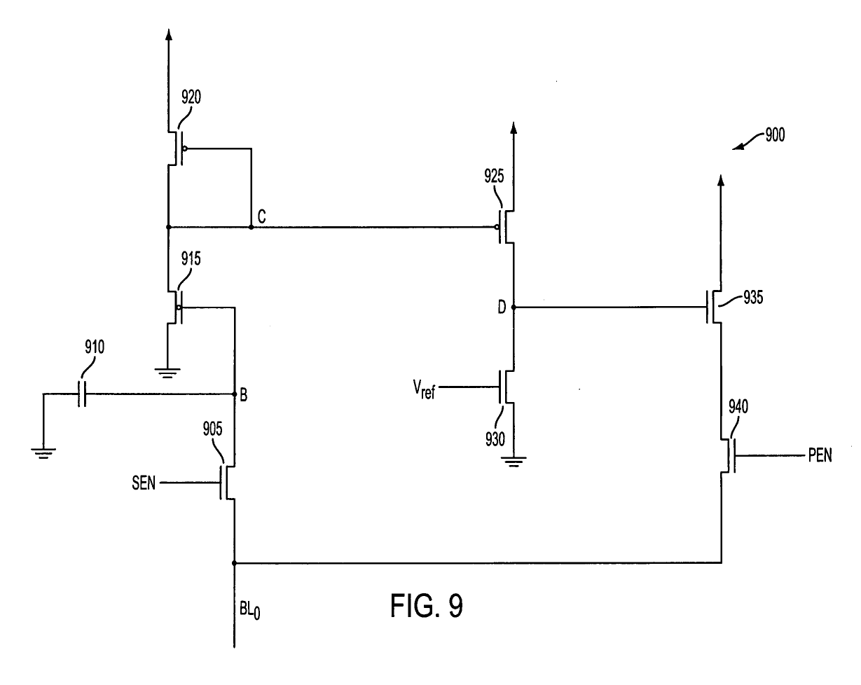

FIG. 9 depicts a second circuit 900 for producing a bit line programming voltage V_{bit} according to an embodiment of the invention for use when the cell 11 is set to a known erase threshold value, or to a known low value, and a threshold value V₂ is to be measured as described above in FIGS. 3-7C. Circuit 900 includes a first n-type enable transistor 905 controlled at its gate by a sensing enable signal SEN with a first source/drain region connected to the bit line BL₀, and a second source/drain region connected to a first node B. A capacitor 910 is connected at one terminal to node B, and the other terminal to a ground potential. Circuit 900 further includes a low threshold voltage NMOS transistor 915, which has its gate coupled to node B, a first source/drain region connected to a ground potential, and a second source/drain region connected to a second node C. Typically, the threshold values of transistor 915 is about 0.1V to about 0.2V. Also connected to node C is the gate and a first source/drain region of a first p-type transistor 920, which functions as a load element to adjust the value of the correlation factor k. The second source/drain region of transistor 920 is connected to a voltage source. Node C is further connected to the gate of a second p-type transistor 925. Transistor 925 has a first source/drain region connected to a voltage source and a second source/drain region connected to an output node D.

Also connected to output node D is a first source/drain region of a second n-type transistor 930, which has a second source/drain region coupled to a ground potential and a gate receiving a reference voltage V_{ref}. Output node D is further coupled to the gate of a third n-type transistor 935, which has a first source/drain region connected to a voltage source and a second source/drain region connected to a first source/drain region of a fourth n-type transistor 940, which is activated by a programming enable signal PEN. The second source/drain region of transistor 940 is coupled to the bit line BL₀. An output voltage Vₒᵤₜ at output node D, and the voltage on the capacitor 910, satisfies the following equation:

Vₒᵤₜ=k*V_{bit} (11)

During operation, a compensation voltage is applied to the bit line BL₀. During the testing and verifying operations, the first and second enabling transistors 12, 17 (FIG. 1) are turned on, and the sensing enable signal SEN activates the first n-type enable transistor 905. A test pulse P₂ is applied to the word line WL₁, and a threshold value V₂ is measured and stored as described above in FIGS. 3-7C.

During programming, the programming enable signal PEN activates the fourth n-type transistor 940, and the sensing enable signal SEN is turned off to deactivate the first n-type enable transistor 905. The output voltage Vₒᵤₜ is measured at output node D, and the bit line voltage V_{bit} is determined according to equations (3) and (11), and does not require direct measurement. The programming pulse voltage Pₑ can then be calculated according to equation (5) and applied as described above.

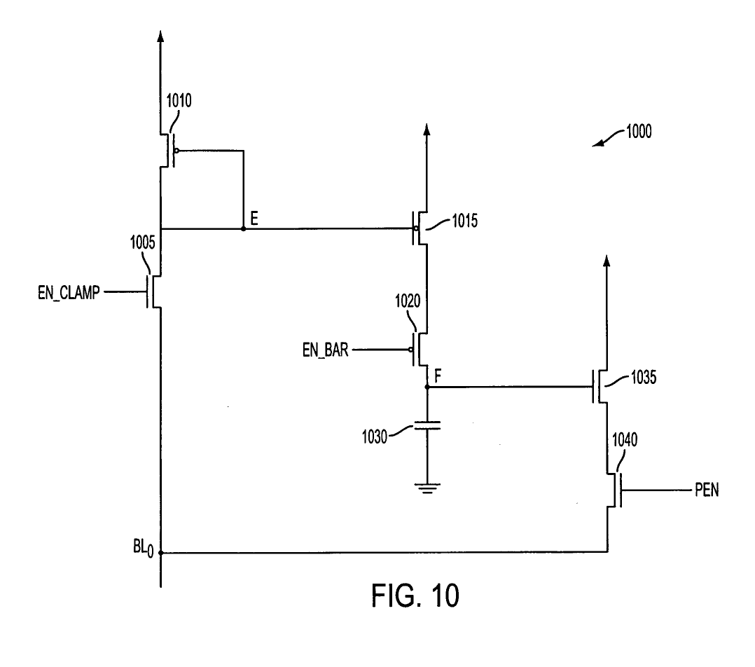

FIG. 10 depicts a third circuit 1000 for producing a bit line programming voltage V_{bit} according to an embodiment of the invention for use when the cell 11 is set to a known erase threshold value, or to a known low value, and a threshold value V₂ is to be measured as described above in FIGS. 3-7C. Circuit 1000 includes a first enable transistor 1005 controlled at its gate by a first sensing enable signal EN_clamp with a first source/drain region connected to the bit line BL₀, and a second source/drain region connected to a first node E. Circuit 1000 further includes a p-type transistor 1010, which has its gate and a first source/drain region coupled to node E, and a second source/drain region connected to a voltage source. Transistor 1010 functions as a load element to adjust the value of the correlation factor k. Also connected to node E is the gate of a low threshold voltage NMOS transistor 1015. A first source/drain region of transistor 1015 is connected to a voltage source, and the second source/drain region of transistor 1015 is coupled to a first source/drain region of a second enable transistor 1020, controlled at its gate by a second sensing enable signal EN_bar. The second source/drain region of transistor 1020 is coupled to output node F.

Output node F is further connected to the gate of a first n-type transistor 1035 and to one terminal of a capacitor 1030. The other terminal of capacitor 1030 is coupled to a ground potential. Transistor 1035 has a first source/drain region connected to a voltage source and a second source/drain region connected to a first source/drain region of a second n-type transistor 1040, which is activated by a programming enable signal PEN. The second source/drain region of transistor 1040 is coupled to the bit line BL₀. An output voltage Vₒᵤₜ at output node F, and the voltage on the capacitor 1030, satisfies the following equation, where I_{cell} is the current through the cell to be programmed:

Vₒᵤₜ=k*I_{cell} (12)

where k includes the resistance of the load element of transistor 1010.

During operation, an offset voltage V_{offset} is applied to the bit line BL₀. During the testing and verifying operations, the first and second enabling transistors 12, 17 (FIG. 1) are turned on, and the first and second sensing enable signals EN_clamp, EN_bar respectively activate the first and second enable transistors 1005, 1020. A test pulse P₂ is applied to the word line WL₁, and a threshold value V₂ is measured and stored as described above in FIGS. 3-7C.

During programming, the programming enable signal PEN activates the second n-type transistor 1040, and the first and second sensing enable signals EN_clamp, EN_bar are turned off to deactivate the first and second enable transistors 1005, 1020. The output voltage Vₒᵤₜ is measured, and the bit line voltage is determined according to equations (3) and (12), and does not require direct measurement. The programming pulse voltage Pₑ can then be calculated according to equation (5) and applied as described above.

It should be noted that other logic and transistor types, as well as other storage circuits may be used within the scope of the invention, and embodiments of the invention are not intended to be limited to the foregoing description. It should also be noted that the embodiments of the invention may be used to program single-level flash memory cells for storing one binary bit, in which a single Vₜ is programmed into the cell, or to program multi-level flash memory cells for storing a plurality of binary bits, in which of a plurality of Vₜ values is programmed into the cell.

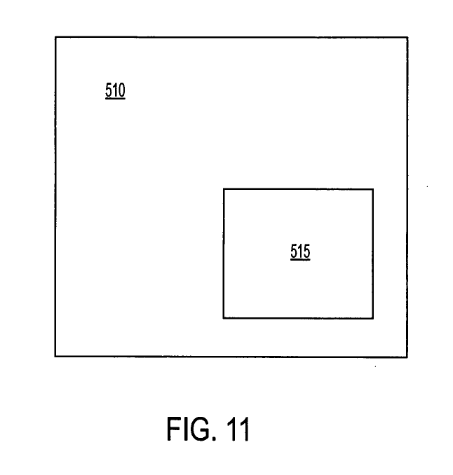

FIG. 11 depicts a flash memory device 510 including a NAND flash memory 515 programmed by adaptive programming pulses in accordance with the embodiments of the invention.

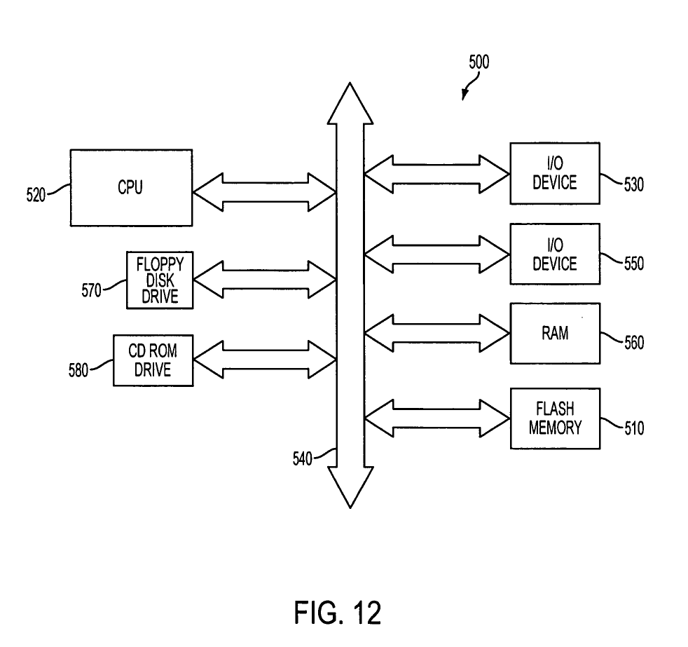

FIG. 12 depicts a block diagram of a simplified processor system 500 utilizing a memory device, e.g., the flash memory device 510 (FIG. 11), constructed in accordance with embodiments of the present invention. That is, the memory device 510 is programmed by adaptive programming pulses in accordance with the embodiments of the invention. The processor system 500 may be a computer system, a process control system (e.g. a camera, cell phone, personal digital assistant) or any other system employing a processor and associated memory. The system 500 includes a central processing unit (CPU) 520, e.g., a microprocessor, that communicates with the flash memory 510 and an I/O device 530 over a bus 540. It must be noted that the bus 540 may be a series of buses and bridges commonly used in a processor system, but for convenience purposes only, the bus 540 has been illustrated as a single bus. A second I/O device 550 is illustrated, but is not necessary to practice the invention. The processor system 500 also includes random access memory (RAM) device 560 and may include a read-only memory (ROM) device (not shown), and peripheral devices such as a floppy disk drive 570 and a compact disk (CD) ROM drive 580 that also communicate with the CPU 520 over the bus 540 as is well known in the art. The system 500 may include any device which incorporates a flash memory device 510 programmed by adaptive programming pulses in accordance with the embodiments of the invention.

While the invention has been described in detail in connection with embodiments known at the time, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. For example, the invention may be used for both single- and multi-level floating gate transistors. Additional test pulses may be used, as well as different functions for the extrapolation of the estimated programming pulse voltage. Furthermore, other programming voltage levels may be used to achieve the invention.

Thus, the invention is not to be seen as limited by the foregoing description, but is only limited by the scope of the appended claims.

What is claimed as new and desired to be protected by Letters Patent of the United States is:

1. A method of operating a flash memory cell comprising:
applying a first bit line voltage to a bit line coupled to the cell;
applying a first test voltage to a word line coupled to the cell;
storing a first threshold voltage value for the cell;
applying a second test voltage to the word line;
storing a second threshold voltage value for the cell; and
determining a programming pulse voltage for the cell from the first and second stored threshold voltage values.

2. The method of claim 1, further comprising:
applying the programming pulse voltage to the cell.

3. The method of claim 2, wherein applying the programming pulse voltage comprises:
applying a maximum programming voltage to the word line; and
applying a bit line programming voltage to the bit line to produce the determined programming pulse voltage.

4. The method of claim 1, further comprising:
applying a fractional multiple of the programming pulse voltage to the cell;
determining if the cell is programmed to a desired threshold voltage level; and
if not, applying a larger programming pulse voltage to the cell.

5. The method of claim 1, further comprising configuring the cell as a single-level flash memory cell.

6. The method of claim 1, further comprising configuring the cell as a multi-level flash memory cell.

7. The method of claim 1, further comprising applying the first bit line voltage and applying the first test voltage during a cell erase operation.

8. The method of claim 1, further comprising applying the first bit line voltage and applying the first test voltage during a cell programming operation.

9. An apparatus for operating a flash memory cell comprising:
a bit line voltage source coupled to a bit line of the cell;
a word line voltage source for producing at least two word line voltages, the word line voltage source being coupled to a word line of the cell;
a first sample-and-hold circuit for sampling and storing a first threshold voltage value of the cell produced in response to a bit line voltage and one of the word line voltages; and
a first determining circuit for determining a programming pulse voltage for the cell based on the first and second threshold voltage values.

10. The apparatus of claim 9, further comprising a second sample-and-hold circuit for sampling and storing a second threshold voltage value of the cell produced in response to the bit line voltage and the other word line voltage.

11. The apparatus of claim 10, wherein:
the first sample and hold circuit comprises:
a first NAND circuit, the first NAND circuit having a first input coupled to the bit line, a second input coupled to a first enable signal, and an output,
a first transistor, the first transistor configured to receive the output of the first NAND circuit at a gate,
a first storage capacitance circuit, the first storage capacitance circuit having a first terminal coupled to a first source/drain region of the first transistor, and a second terminal coupled to a first voltage source, and
an operational amplifier, the operational amplifier having an inverting input coupled to an output, a non-inverting input coupled to a second voltage source, and the output further coupled to a second source/drain region of the first transistor; and
the second sample and hold circuit comprises:
a second NAND circuit, the second NAND circuit having a first input coupled to the bit line, a second input coupled to a second enable signal, and an output,
a second transistor, the second transistor configured to receive the output of the second NAND circuit at a gate, and
a second storage capacitance circuit, the second storage capacitance circuit having a first terminal coupled to a first source/drain region of the first transistor, and a second terminal coupled to the first voltage source, and a second source/drain region coupled to the output of the operational amplifier.

12. The apparatus of claim 9, wherein the bit line voltage source and the word line voltage source are configured to apply the programming pulse voltage to the cell.

13. The apparatus of claim 12, wherein:
the word line voltage source configured to apply a maximum programming voltage to the word line; and
the bit line voltage source configured to apply a bit line programming voltage to the bit line to produce the programming pulse voltage.

14. The apparatus of claim 13, wherein the bit line voltage source comprises:
a first operational amplifier, the first operational amplifier configured to receive the second threshold voltage value at an inverting input and the determined programming pulse voltage at a non-inverting input, and configured to output an intermediate voltage; and
a second operational amplifier, the second operational amplifier configured to receive the intermediate voltage at an inverting input and a reference voltage at a non-inverting input, and configured to output the bit line programming voltage.

15. The apparatus of claim 13, wherein the bit line voltage source comprises:
a first difference circuit, the first difference circuit configured to receive the second threshold voltage value at an inverting input and the determined programming pulse voltage at a non-inverting input, and configured to output an intermediate voltage; and
a second difference circuit, the second difference circuit configured to receive the intermediate voltage at an inverting input and a reference voltage at a non-inverting input, and configured to output the bit line programming voltage.

16. The apparatus of claim 13, wherein the bit line voltage source comprises:
a first enable transistor, the first enable transistor configured to be controlled at a gate of the first enable transistor by an enable signal, the first enable transistor having a first source/drain region coupled to the bit line, and a second source/drain region coupled to a first node;
a capacitor, the capacitor coupled at a first terminal to the first node, and coupled at a second terminal to a ground potential;
a second transistor, the second transistor having a gate coupled to the first node, a first source/drain region coupled to a ground potential, and a second source/drain region coupled to a second node;
a third transistor, the third transistor having a gate and a first source/drain region coupled to the second node, and a second source/drain region coupled to a voltage source;
a fourth transistor, the fourth transistor having a gate coupled to the second node, a first source/drain region coupled to the voltage source, and a second source/drain region coupled to an output node;
a fifth transistor, the fifth transistor having a first source/drain region coupled to the output node, a second source/drain region coupled to a ground potential, and a gate coupled to a reference voltage;
a sixth transistor, the sixth transistor having a gate coupled to the output node, and a first source/drain region coupled to the voltage source; and
a seventh transistor, the seventh transistor having a first source/drain region coupled to a second source/drain region of the sixth transistor, and a second source/drain region coupled to the bit line.

17. The apparatus of claim 13, wherein the bit line voltage source comprises:
a first enable transistor, the first enable transistor configured to be controlled at a gate of the first enable transistor by a first enable signal, the first enable transistor having a first source/drain region coupled to the bit line, and a second source/drain region coupled to a first node;
a second transistor, the second transistor having a gate and a first source/drain region coupled to the first node, and a second source/drain region coupled to a voltage source;
a third transistor, the third transistor having a gate coupled to the first node, and a first source/drain region coupled the voltage source;
a fourth enable transistor, the fourth enable transistor controlled at a gate of the fourth enable transistor by a second enable signal, the fourth enable transistor having a first source/drain region coupled to a second source/drain region of the third transistor, and a second source/drain region coupled to an output node;
a fifth transistor, the fifth transistor having a gate coupled to the output node, and a first source/drain region coupled to the voltage source;
a capacitor, the capacitor having a first terminal coupled to the output node and a second terminal coupled to a ground potential; and
a sixth transistor, the sixth transistor having a first source/drain region coupled to a second source/drain region of the fifth transistor, and a second source/drain region coupled to the bit line.

18. The apparatus of claim 9, further comprising a second determining circuit, wherein:
the bit line voltage source and the word line voltage source are configured to apply a fractional multiple of the programming pulse voltage to the cell,
the second determining circuit is configured to determine if the cell is programmed to a desired threshold voltage level, and
if not, the bit line voltage source and the word line voltage source are configured to apply a larger programming pulse voltage to the cell.

19. The apparatus of claim 9, wherein the cell comprises a single-level flash memory cell.

20. The apparatus of claim 9, wherein the cell comprises a multi-level flash memory cell.

21. A processing system comprising:
a processor; and
an apparatus for operating a flash memory cell comprising:
a bit line voltage source coupled to a bit line of the cell,
a word line voltage source for producing at least two word line voltages, the word line voltage source being coupled to a word line of the cell,
a first sample-and-hold circuit for sampling and storing a first threshold voltage value of the cell produced in response to a bit line voltage and one of the word line voltages, and
a determining circuit for determining a programming pulse voltage for the cell based on the first and second threshold voltage values.

22. The processing system of claim 21, further comprising: a second sample-and-hold circuit for sampling and storing a second threshold voltage value of the cell produced in response to the bit line voltage and the other word line voltage.

23. The processing system of claim 22, wherein the bit line voltage source and the word line voltage source are configured to apply the programming pulse voltage to the cell.

24. The processing system of claim 23, wherein:
the word line voltage source is configured to apply a maximum programming voltage to the word line; and
the bit line voltage source is configured to apply a bit line programming voltage to the bit line to produce the programming pulse voltage.

25. The processing system of claim 21, further comprising a second determining circuit, wherein:
the bit line voltage source and the word line voltage source are configured to apply a fractional multiple of the programming pulse voltage to the cell,
the second determining circuit is configured to determine if the cell is programmed to a desired threshold voltage level, and
if not, the bit line voltage source and the word line voltage source are configured to apply a larger programming pulse voltage to the cell.

26. The processing system of claim 21, wherein the cell comprises a single-level flash memory cell.

27. The processing system of claim 21, wherein the cell comprises a multi-level flash memory cell.

28. An apparatus for operating a flash memory cell comprising:
means for applying a first bit line voltage to a bit line coupled to the cell;
means for applying a first test voltage to a word line coupled to the cell;
means for storing a first threshold voltage value for the cell;
means for applying a second test voltage to the word line;
means for storing a second threshold voltage value for the cell; and
means for determining a programming pulse voltage for the cell from the first and second stored threshold voltage values.

29. The apparatus of claim 28, further comprising:
means for applying the programming pulse voltage to the cell.

30. The apparatus of claim 29, wherein applying the programming pulse voltage comprises:
means for applying a maximum programming voltage to the word line; and
means for applying a bit line programming voltage to the bit line to produce the programming pulse voltage.

31. The apparatus of claim 28, further comprising:
means for applying a fractional multiple of the programming pulse voltage to the cell;
means for determining if the cell is programmed to a desired threshold voltage level; and
means for applying a larger programming pulse voltage to the cell if the cell is not programmed to the desired threshold voltage level.

32. The apparatus of claim 28, wherein the cell comprises a single-level flash memory cell.

33. The apparatus of claim 28, wherein the cell comprises a multi-level flash memory cell.

34. A method of operating a flash memory cell comprising:
discharging a bit line;
applying an offset voltage to a source/drain transistor coupled to the bit line;
applying a word line voltage to a word line, the applied word line voltage being gradually increased from approximately 0V to a maximum sweep voltage;
setting a latch when a sensing voltage on the bit line reaches a sensing threshold voltage;
storing a value corresponding to the word line voltage; and
calculating a cell threshold value based on the value corresponding to the word line voltage and the offset voltage.

35. The method of claim 34, wherein the applied word line voltage is increased by increments or continuously.

36. The method of claim 34, further comprising configuring the latch as a pair of looped inverters.

37. A flash memory device comprising:
an apparatus for operating a flash memory cell, the apparatus configured to:
discharge a bit line;
apply an offset voltage to a source/drain transistor coupled to the bit line;
apply a word line voltage to a word line, the applied word line voltage being gradually increased from approximately 0V to a maximum sweep voltage;
set a latch when a sensing voltage on the bit line reaches a sensing threshold voltage;
store a value corresponding to the word line voltage; and
calculate a cell threshold value based on the value corresponding to the word line voltage and the offset voltage.

38. A flash memory device comprising:
an apparatus for operating a flash memory cell, the apparatus configured to:
apply a first bit line voltage to a bit line coupled to the cell;
apply a first test voltage to a word line coupled to the cell;
store a first threshold voltage value for the cell;
apply a second test voltage to the word line;
store a second threshold voltage value for the cell; and
determine a programming pulse voltage for the cell from the first and second stored threshold voltage values.

39. The device of claim 38, wherein the apparatus is further configured to:
apply the programming pulse voltage to the cell.

40. The device of claim 39, wherein the applying the programming pulse voltage comprises:
applying a maximum programming voltage to the word line; and
applying a bit line programming voltage to the bit line to produce the determined programming pulse voltage.

41. The device of claim 38, wherein the apparatus is further configured to:
apply a fractional multiple of the programming pulse voltage to the cell;
determine if the cell is programmed to a desired threshold voltage level; and
if not, apply a larger programming pulse voltage to the cell.

42. The device of claim 38, wherein the apparatus is further configured to apply the first bit line voltage and apply the first test voltage during a cell erase operation.

43. The device of claim 38, wherein the apparatus is further configured to apply the first bit line voltage and apply the first test voltage during a cell programming operation.

44. A flash memory device comprising:
an apparatus for operating a flash memory cell, the apparatus configured to:
perform a cell erase operation, the cell erase operation setting the cell to an erase threshold value;
apply a bit line voltage to a bit line coupled to the cell;
apply a test voltage to a word line coupled to the cell;
store a threshold voltage value for the cell; and
determine a programming pulse voltage for the cell from the erase threshold value and the stored threshold voltage value.

45. A method of operating a flash memory cell comprising:
performing a cell erase operation, the cell erase operation setting the cell to an erase threshold value;
applying a bit line voltage to a bit line coupled to the cell;
applying a test voltage to a word line coupled to the cell;
storing a threshold voltage value for the cell; and
determining a programming pulse voltage for the cell from the erase threshold value and the stored threshold voltage value.
